(19) United States
(12) Patent Application Publication
(10) Pub. No.: US 2024/0145536 A1
(43) Pub. Date: May 2, 2024

(54) SEMICONDUCTOR DEVICE STRUCTURE WITH VERTICAL TRANSISTOR OVER UNDERGROUND BIT LINE

(71) Applicant: Invention And Collaboration Laboratory Pte. Ltd., Singapore (SG)

(72) Inventor: Chao-Chun Lu, Taipei City (TW)

(73) Assignee: Invention And Collaboration Laboratory Pte. Ltd., Singapore (SG)

(21) Appl. No.: 18/494,783

(22) Filed: Oct. 26, 2023

Related U.S. Application Data
(60) Provisional application No. 63/419,740, filed on Oct. 27, 2022.

(51) Int. Cl. H01L 29/06; H10B 12/00

(52) U.S. Cl. CPC H01L 29/0649; H10B 12/395; H10B 12/482; H10B 12/485; H10B 12/488

(57) ABSTRACT

A semiconductor device structure includes a semiconductor substrate, an active region, a STI (shallow trench isolation) region, and an interconnection layer. The semiconductor substrate has an original surface. The active region is within the semiconductor substrate, wherein the active region includes a transistor and the transistor includes a gate structure with a bottom surface under the original surface, a first conductive region, and a second conductive region. The STI region surrounds the active region. The interconnection layer extends beyond the transistor and electrically coupled to the transistor at a connection position under the gate structure.

### CROSS REFERENCE TO RELATED APPLICATIONS

This application claims the benefit of U.S. Provisional Application No. 63/419,740, filed on Oct. 27, 2022. The content of the application is incorporated herein by reference.

### BACKGROUND OF THE INVENTION

### 1. Field of the Invention

The present invention relates to a semiconductor device structure, and particularly to a DRAM (Dynamic Random Access Memory) cell including a capacitor over a vertical transistor which is then over underground bit lines (TOB-cell) to shrink the area of the DRAM cell.

### 2. Description of the Prior Art

One of the most important volatile-memory integrated circuits is the DRAM (Dynamic Random Access Memory) using the 1T1C memory cell, which not only provides the best cost-performance function as main memory and/or buffer memory for computing and communication applications but also has acted as the best driver for technology scaling-down to sustain the Moore's Law by scaling down minimum feature size on the silicon from several micrometers down to twenty nanometers or so. However, the now available technology-node of DRAM is above 10 to 12 nanometers which cannot still match the most advanced technology-node (e.g., 5 nanometer) used in the current logic technology. The major problem is that a structure of the 1T1C memory cell is very hard to be further scaled down by even using very aggressive design rules, scaled access transistor (i.e. 1T) design and three-dimensional storage capacitor (i.e. 1C) such as a stacked capacitor over part of the access transistor and isolation areas or a very deep trench capacitor.

The difficulties for the 1T1C memory cell are elaborated here though they are well-known problems even under huge financial, and research and development investments on technology, design and equipment. To give a few examples of the difficulties: (1) the structure of the access transistor suffers unavoidable but more serious current leakage problem to degrade the 1T1C memory cell storage functions such as reducing the DRAM refresh time; (2) the complexities of arranging the word lines, bit lines and storage capacitors on their geometric and topographic structures and connections to the gates, sources and drains of the access transistors are getting much worse for scaling down; (3) the trench capacitor suffers too large aspect ratio of the depth versus opening size and is almost halted at the 14 nm node; (4) the stacked capacitor suffers the worsen topography and there is almost no space for the contact spaces between the storage electrode to the source of the access transistor after twisting the active region from 20 degree to over 50 degree, etc. In addition, the allowable space for the bit line contact to the drain of the access transistor is getting so small but a self-aligned feature must still be struggled to maintain; (5) the worsen leakage current problem demands enhancing the capacitance and keeping increasing the height of the capacitor to have a larger capacitance area unless a much high-K dielectric insulator material for the storage capacitance can be discovered; (6) without technology breakthroughs of solving the above difficulties all increasing demands on better reliability, quality and resilience of DRAM chips under increasingly demanding higher density/capacity and performance are getting harder to be met, and so on.

However, the prior art has no good technology to solve the above-mentioned problems, so how to design a new structure of the 1T1C memory cell to solve the above-mentioned problems has become an important issue for a designer of the 1T1C memory cell.

### SUMMARY OF THE INVENTION

An embodiment of the present invention provides a includes a semiconductor substrate, an active region, a STI (shallow trench isolation) region, and an interconnection layer. The semiconductor substrate has an original surface. The active region is within the semiconductor substrate, wherein the active region includes a transistor and the transistor includes a gate structure with a bottom surface under the original surface, a first conductive region, and a second conductive region. The STI region surrounds the active region. The interconnection layer extends beyond the transistor and electrically coupled to the transistor at a connection position under the gate structure.

According to one aspect of the present invention, the interconnection layer is disposed within the STI region and under the original surface, and the interconnection layer is isolated from the semiconductor substrate.

According to one aspect of the present invention, the second conductive region includes two sub-regions located on two sides of the gate structure respectively, and the first conductive region is lower than the second conductive region.

According to one aspect of the present invention, the transistor further includes two vertical channel regions separate from each other, wherein the first conductive region is electrically connected to the two sub-regions of the second conductive region through the vertical channel region.

According to one aspect of the present invention, the semiconductor device structure further includes a highly doped semiconductor region next to one of the two vertical channel regions, the highly doped semiconductor region extends downward from the original surface, and a dopant type of the highly doped semiconductor region is different from that of the first conductive region.

According to one aspect of the present invention, the interconnection layer is coupled to the first conductive region of the transistor at the connection position through a connection contact which is a highly doped semiconductor plug, or the interconnection layer is directly coupled to the first conductive region of the transistor at the connection position.

According to one aspect of the present invention, the semiconductor device structure further includes a capacitor electrically connected to the second conductive region, and the interconnection layer is a bitline electrically connected to the first conductive region.

According to one aspect of the present invention, the semiconductor device structure further includes a wordline electrically connected to the gate structure, and the wordline penetrates through the second conductive region.

According to one aspect of the present invention, the semiconductor device structure further includes a dielectric plug between the gate structure and the first conductive region.

Another embodiment of the present invention provides a semiconductor device structure. The semiconductor device structure includes a semiconductor substrate, a first active region, a second active region, a shallow trench isolation (STI) region, a transistor, and an interconnection layer. The semiconductor substrate has an original surface. The semiconductor substrate has a semiconductor surface. The shallow trench isolation (STI) region is between the first active region and the second active region. The transistor is formed based on the first active region and includes a gate structure, a first conductive region, and a second conductive region. The interconnection layer is within the STI region and electrically coupled to the first conductive region of the transistor, wherein the first conductive region is below the gate structure of the transistor.

According to one aspect of the present invention, a side surface of the interconnection layer abuts against a side surface of a connection contact which directly connects the first conductive region of the transistor.

According to one aspect of the present invention, the interconnection layer extends along the STI region and is positioned under the semiconductor surface.

According to one aspect of the present invention, the STI region includes a first spacer contacted to the first active region and a second spacer contacted to the second active region, and a material of the first spacer is different from that of the second spacer.

According to one aspect of the present invention, a side surface of the interconnection layer abuts against a side surface of the first conductive region of the transistor.

According to one aspect of the present invention, the semiconductor device structure further includes a capacitor electrically connected to the second conductive region, and the interconnection layer is a bitline electrically connected to the first conductive region.

According to one aspect of the present invention, the semiconductor device structure further includes a wordline electrically connected to the gate structure, wherein the second conductive region includes two sub-regions located on two sides of the gate structure, and the wordline penetrates through the two sub-regions of the second conductive region.

Another embodiment of the present invention provides a includes a semiconductor substrate, an active region, a shallow trench isolation (STI) region, a transistor, and an interconnection layer. The semiconductor substrate has an original surface. The semiconductor substrate has a semiconductor surface. The STI region surrounds the active region. The transistor is within the active region, and the transistor includes a gate structure, a first conductive region, and a second conductive region. The interconnection layer is within the STI region and electrically coupled to the first conductive region of the transistor, wherein the second conductive region is above the first conductive region and comprises two sub-regions located on two sides of the gate structure respectively.

According to one aspect of the present invention, the transistor further includes two vertical channel regions separate from each other, wherein the first conductive region is electrically connected to the two sub-regions of the second conductive region through the two vertical channel regions.

According to one aspect of the present invention, the semiconductor device structure further includes a capacitor electrically connected to each of the two sub-regions of the second conductive region of the transistor.

According to one aspect of the present invention, the capacitor includes two electrode pillars connected to the two sub-regions of the second conductive region, respectively.

Another embodiment of the present invention provides a semiconductor device structure. The semiconductor device structure includes a semiconductor bulk substrate, an active region, a STI region, and an interconnection layer. The semiconductor bulk substrate has an original surface. The active region is within the semiconductor bulk substrate, wherein the active region includes a plurality of transistors, each transistor includes a gate structure with a bottom surface under the original surface, a first conductive region electrically coupled to the semiconductor bulk substrate, and a second conductive region. The STI region surrounds the active region. The interconnection layer extends beyond at least one transistor of the plurality of transistors and electrically coupled to the at least one transistor at a connection position under the gate structure of the at least one transistor.

According to one aspect of the present invention, the interconnection layer is a bit line extended beyond the plurality of transistors and electrically coupled to each of the plurality of transistors at a connection position under the gate structure of each transistor, respectively.

According to one aspect of the present invention, the interconnection layer is disposed within the STI region and under the original surface and is isolated from the semiconductor bulk substrate, and the first conductive region of the at least one transistor is directly or indirectly connected to a sidewall of the interconnection layer.

According to one aspect of the present invention, the at least one transistor further includes two vertical channel regions separate from each other, wherein the first conductive region of the at least one transistor is electrically connected to the two sub-regions of the second conductive region of the at least one transistor through the two vertical channel region.

According to one aspect of the present invention, the semiconductor device structure further includes a highly doped semiconductor region next to one of the two vertical channel regions, the highly doped semiconductor region extends downward from the original surface and a dopant type of the highly doped semiconductor region is different from that of the first conductive region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1A is a flowchart illustrating a manufacturing method of a TOB-cell (1T1C cell) array according to an embodiment of the present invention.

FIG. 1B, FIG. 1C, FIG. 1D, FIG. 1E, FIG. 1F, FIG. 1G, FIG. 1H are diagrams illustrating FIG. 1A.

FIG. 2 is a diagram illustrating a top view and a cross-section view along an X direction after the pad-nitride layer and the pad-oxide layer are deposited and the STI is formed.

FIG. 3 is a diagram illustrating depositing and etching back the nitride-1 layer to form nitride-1 spacers, and depositing the SOD and the photoresist layer.

FIG. 4 is a diagram illustrating etching away the upper edge nitride-1 spacer and the SOD not covered by the photoresist layer.

FIG. 5 is a diagram illustrating stripping off the photoresist layer and the SOD, and growing the oxide-1 layer.

FIG. 6 is a diagram illustrating the metal layer being deposited in the trench and planarized by the CMP technique.

FIG. 7 is a diagram illustrating the photoresist layer being deposited and the metal layer corresponding to ends of the active region being etched.

FIG. 8 is a diagram illustrating the photoresist layer being removed and the metal layer being etched back to form the underground bit line.

FIG. 9 is a diagram illustrating the oxide-2 layer being deposited in the trench.

FIG. 10 is a diagram illustrating the oxide-3 layer, the nitride-2 layer, and the photoresist being deposited, and then the unnecessary parts of the oxide-3 layer, the nitride-2 layer, and the photoresist being removed.

FIG. 11 is a diagram illustrating the photoresist layer, the pad-nitride layer, and the pad-oxide layer being removed to reveal the OSS.

FIG. 12 is a diagram illustrating creating the concave and forming the oxide spacer-1 and the nitride spacer-1.

FIG. 13 is a diagram illustrating removing the exposed silicon areas in the concave to form the trench hole and forming the oxide spacer-2 and the nitride spacer-2.

FIG. 14 is a diagram illustrating removing the exposed silicon areas in the trench hole and growing thermal oxide, and creating the sidewall region connected to the underground bitline and depositing in-situ doped n+ polysilicon.

FIG. 15 is a diagram illustrating removing the in-situ doped n+ polysilicon and the thermal oxide, growing the (N+) drain region, and growing thermally the oxide plug in the trench region.

FIG. 16 is a diagram illustrating removing the oxide spacer-2, growing the thermal oxide, and depositing, planarizing, and etching back the TiN layer and the Tungsten layer.

FIG. 17 is a diagram illustrating depositing the nitride layer and then depositing and etching down the oxide layer.

FIG. 18 is a diagram illustrating etching the nitride layer and portion of the oxide layer, and growing the n-type LDD.

FIG. 19 is a diagram illustrating depositing the oxide layer, creating the out-diffuse regions, and etching away the oxide-3 layer, the nitride-2 layer, the pad-nitride layer, and the pad-oxide layer to form the concave.

FIG. 20 is a diagram illustrating forming the oxide spacer-3 and the nitride spacer-3, and anisotropic etching the reveal silicon to form the deep trench.

FIG. 21 is a diagram illustrating growing the in-situ doped p-type single-crystalline silicon layer, and growing thermal oxide to fill completely the trench.

FIG. 22 is a diagram illustrating growing the vertical layer, forming the high-k dielectric layer over the vertical layer as the storage-node insulator, and then forming the thin layer (SiₓGe₁₋ₓ) as the capacitor counter-electrode.

### DETAILED DESCRIPTION

The present invention provides a very compact 1T1C (one-transistor one-capacitor) DRAM (dynamic random access memory) cell structure by using a unique 3D (three-dimensional) construction manufacturing method of forming the 1T and 1C stacked in a very compact planar area. An inventive feature is that an access transistor (i.e. 1T) is positioned over an underground bitline structure; the new cell structure is thus named as TOB-cell (transistor-over-bitline TOB-cell). Another inventive feature is that the manufacturing method counts on only few processing steps which require advanced photolithographic technique and exposure tool but most critical processing steps count on utilizing novel self-alignment and/or self-construction processing methods so that the TOB-cell possesses highly scaled-down capabilities, e.g. which can be shrunk to a cell area of 4.5×2.5 F (or 5×2.5 F) where the minimum feature size F is scalable to a range of −6 nm.

For focusing the TOB-cell invention and its major inventive features, the following manufacturing method is concentrated on specifically constructing the 1T1C cells (i.e. the TOB-cells) only without elaborating on an entire DRAM chip formation which should include other additional processes to form peripheral circuits of the entire DRAM chip.

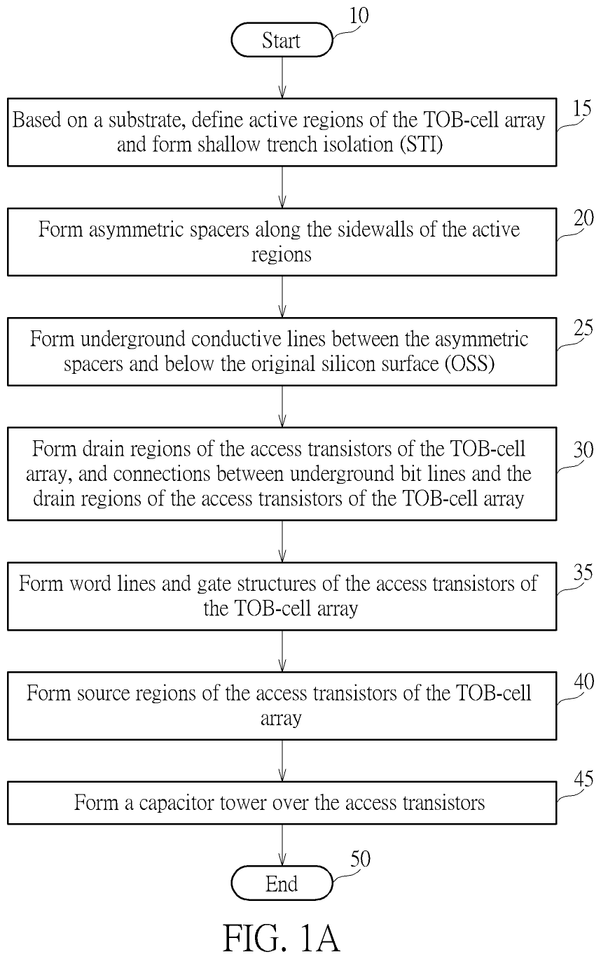

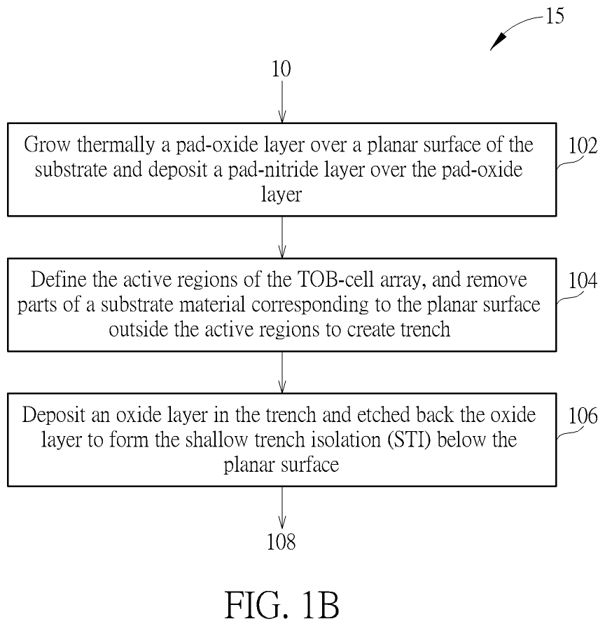

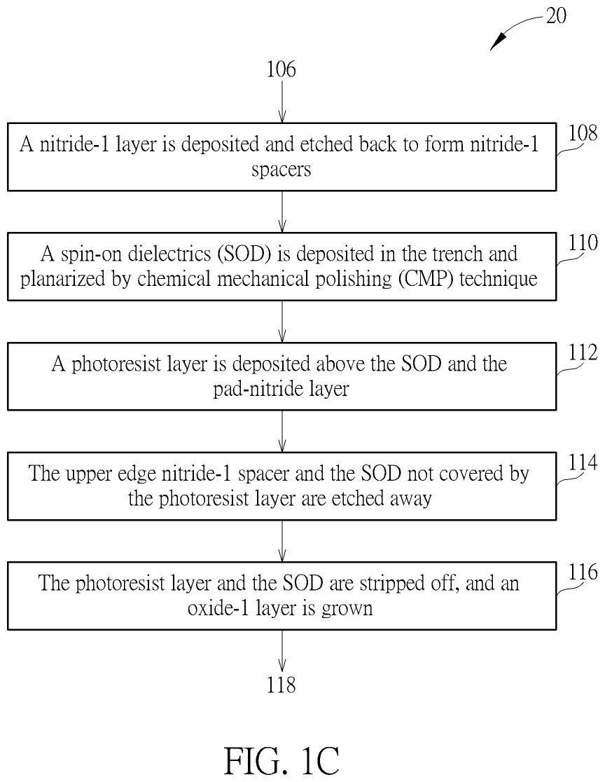

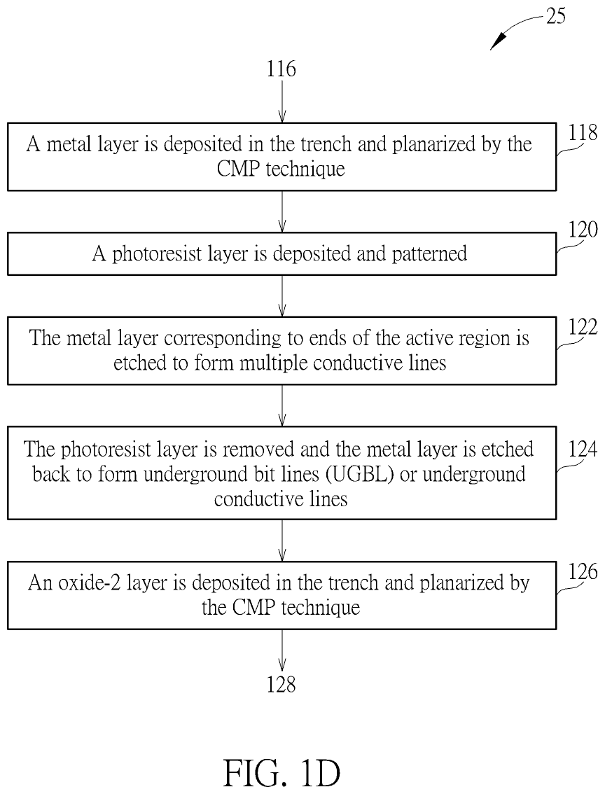

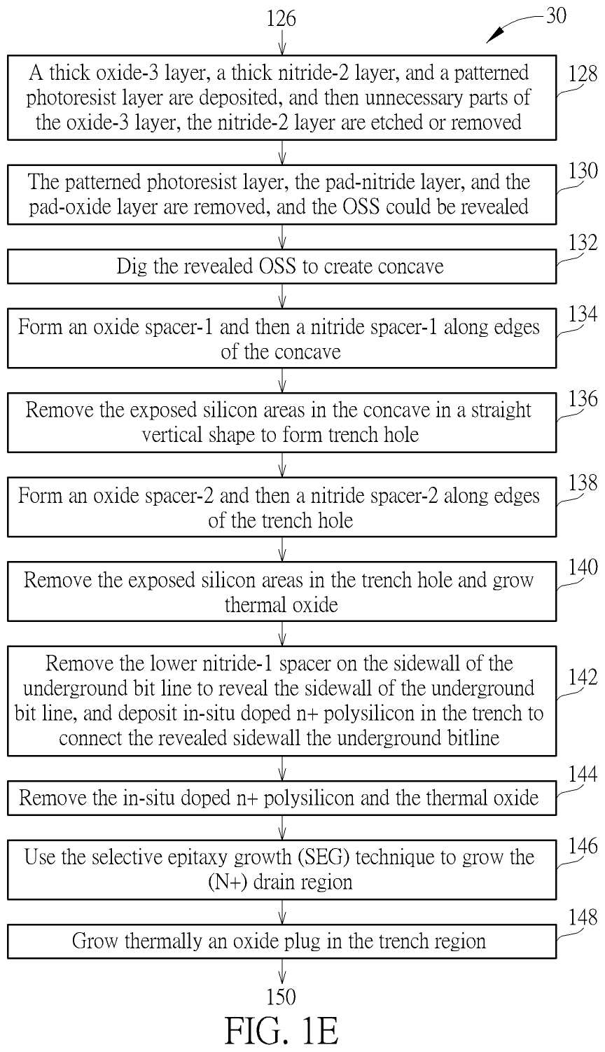

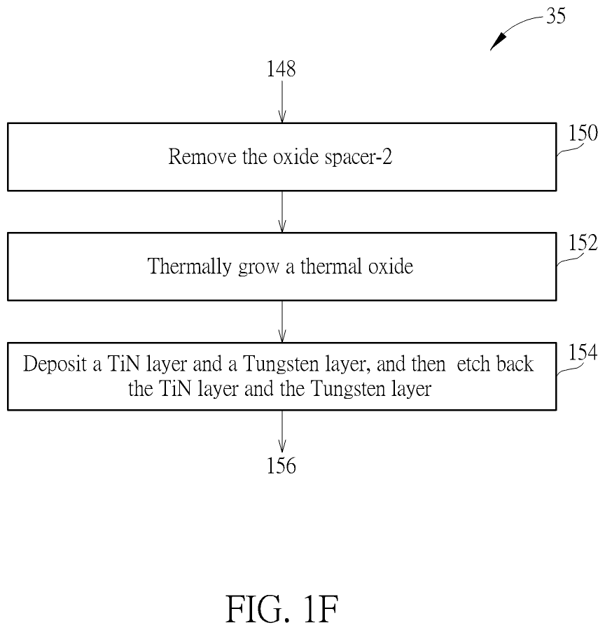

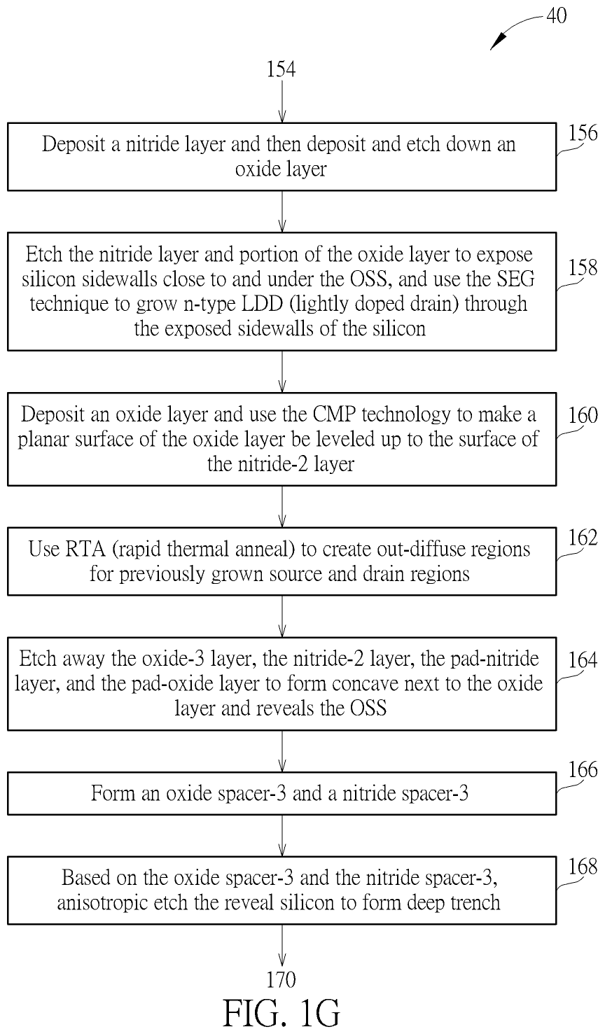

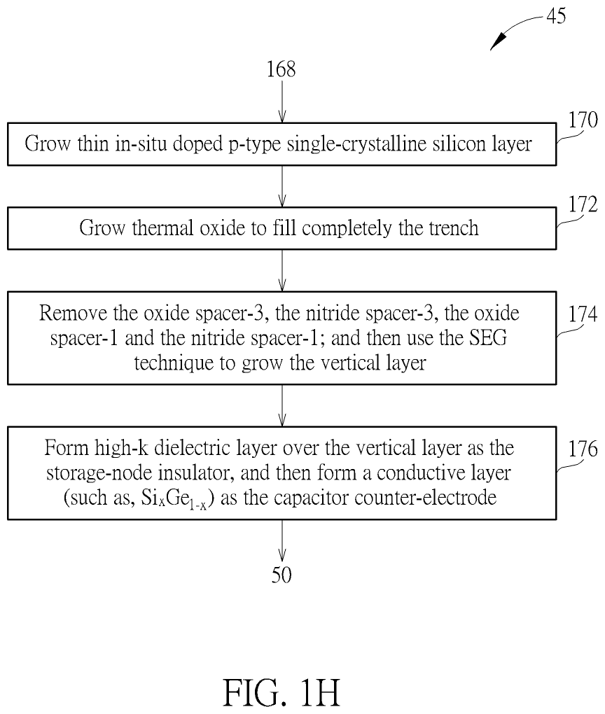

Next, please refer to FIGS. 1A-1F, wherein FIG. 1A is a flowchart illustrating a manufacturing method of a TOB-cell array according to an embodiment of the present invention.

Step 10: Start.

Step 15: Based on a substrate (such as, a p-type silicon substrate), define active regions of the TOB-cell array and form shallow trench isolation (STI).

Step 20: Form asymmetric spacers along the sidewalls of the active regions.

Step 25: Form underground conductive lines (such as bitlines) between the asymmetric spacers and below the original silicon surface (OSS).

Step 30: Form drain regions of the access transistors of the TOB-cell array, and connections between underground bit lines and the drain regions of the access transistors of the TOB-cell array.

Step 35: Form word lines and gate structures of the access transistors of the TOB-cell array.

Step 40: Form source regions of the access transistors of the TOB-cell array.

Step 45: Form a capacitor tower over the access transistors.

Step 50: End.

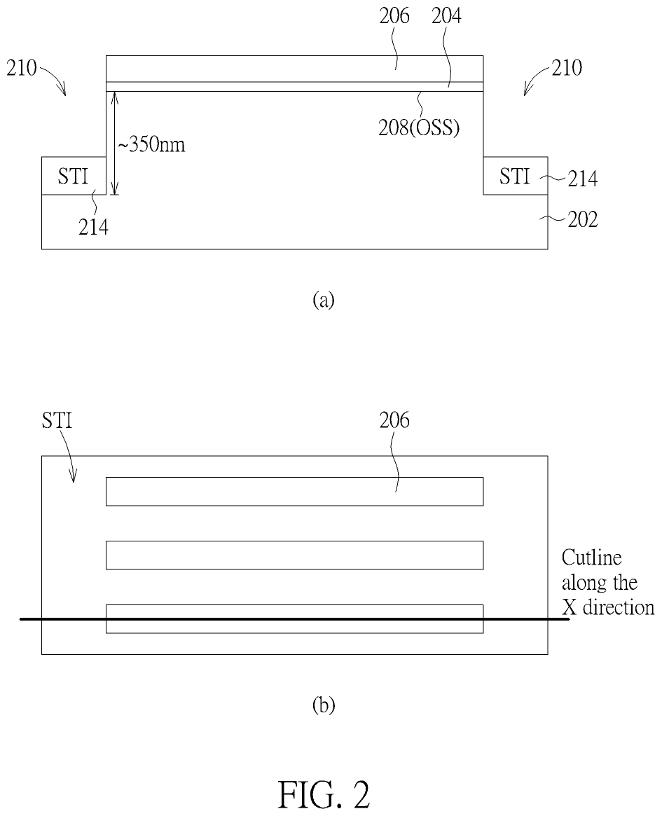

Please refer to FIG. 1B and FIG. 2. Step 15 could include:

Step 102: Grow thermally a pad-oxide layer 204 over a planar surface 208 of the substrate and deposit a pad-nitride layer 206 over the pad-oxide layer 204 (FIG. 2).

Step 104: Define the active regions of the TOB-cell array, and remove parts of a substrate material (such as silicon material) corresponding to the planar surface 208 outside the active regions to create trench 210 (FIG. 2).

Step 106: Deposit an oxide layer 214 in the trench 210 and etched back the oxide layer 214 to form the shallow trench isolation (STI) below the planar surface 208 (FIG. 2).

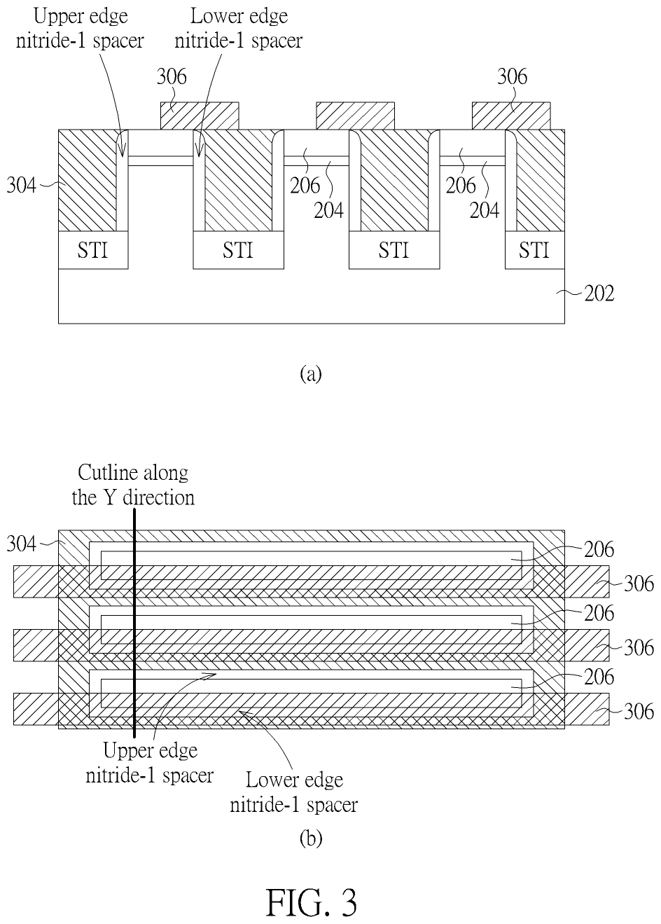

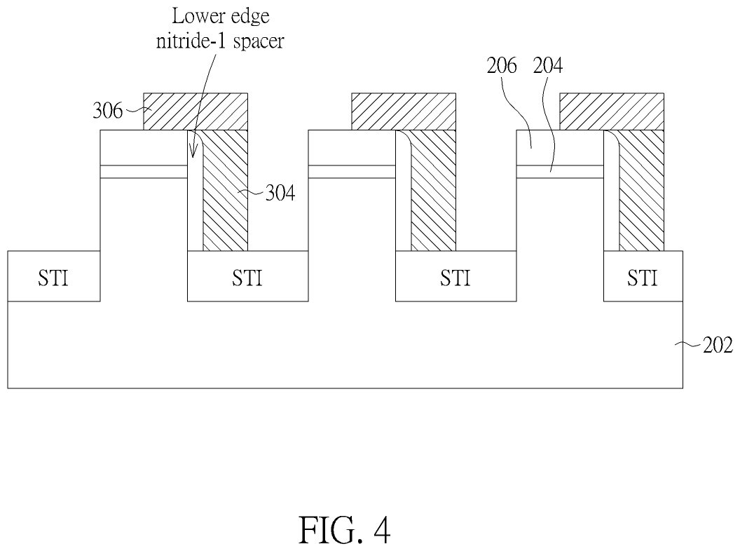

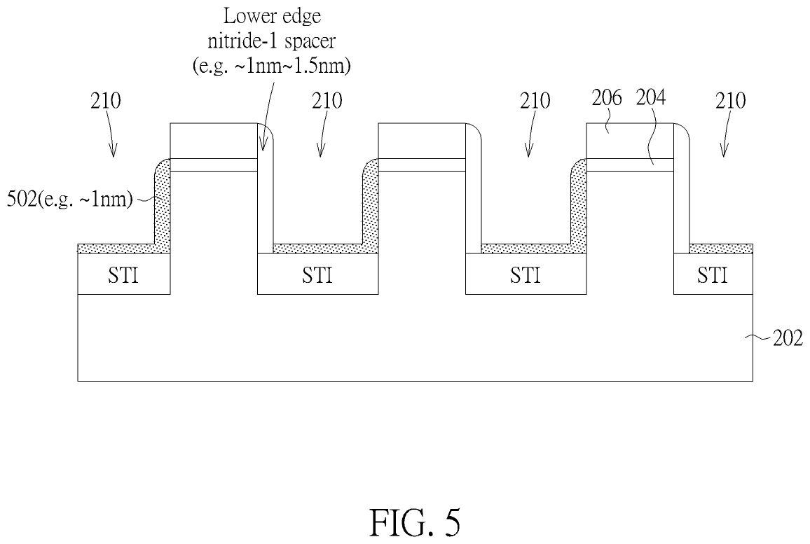

Please refer to FIG. 1C, FIG. 3, FIG. 4, FIG. 5. Step 20 could include:

Step 108: A nitride-1 layer is deposited and etched back to form nitride-1 spacers (FIG. 3).

Step 110: A spin-on dielectrics (SOD) 304 is deposited in the trench 210 and planarized by chemical mechanical polishing (CMP) technique (FIG. 3).

Step 112: A photoresist layer 306 is deposited above the SOD 304 and the pad-nitride layer 206 (FIG. 3).

Step 114: The upper edge nitride-1 spacer and the SOD 304 not covered by the photoresist layer 306 are etched away (FIG. 4).

Step 116: The photoresist layer 306 and the SOD 304 are stripped off, and an oxide-1 layer 502 is grown, such as thermal growth (FIG. 5).

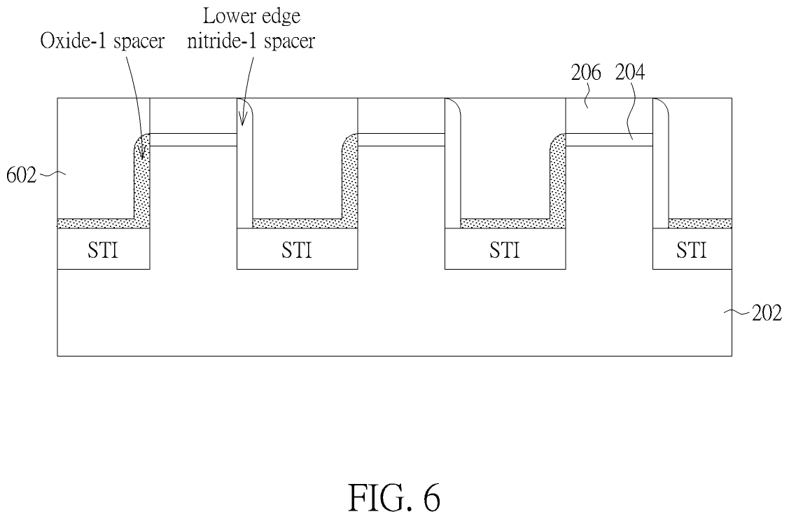

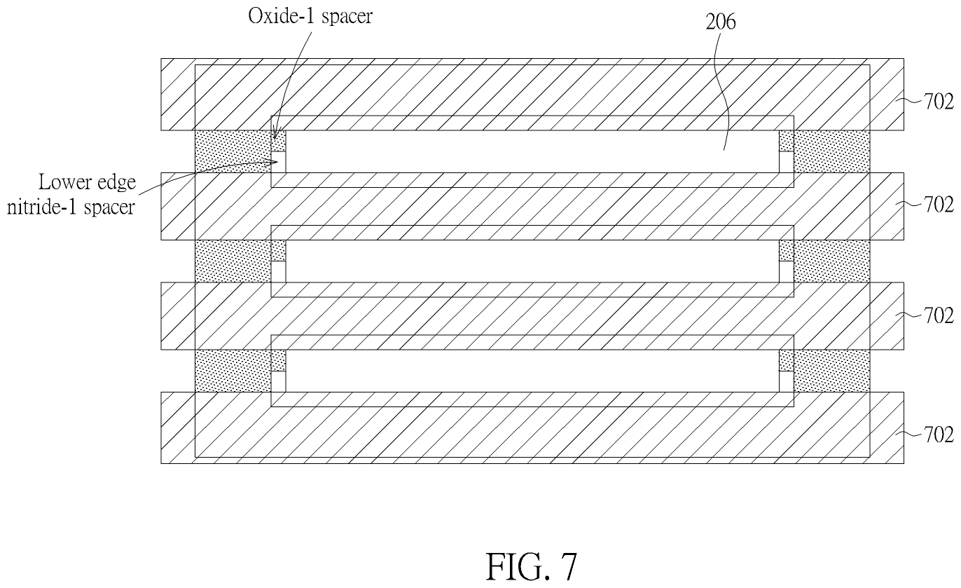

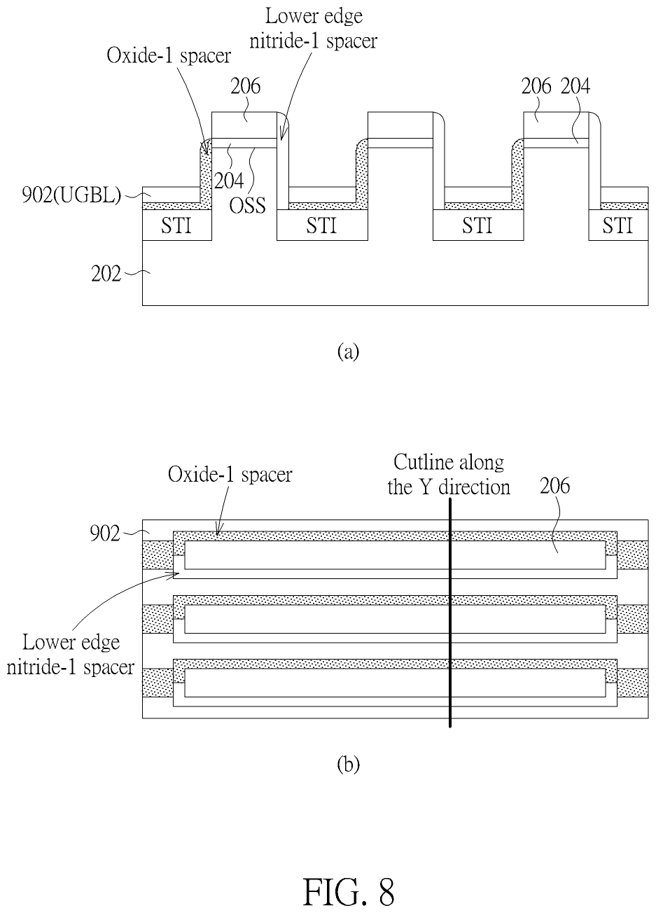

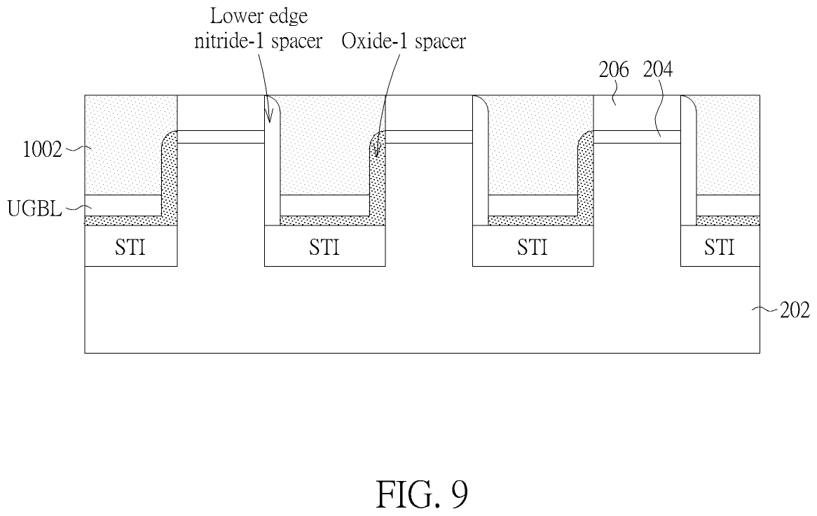

Please refer to FIG. 1D, FIG. 6, FIG. 7, FIG. 8, and FIG. 9. Step 25 could include:

Step 118: A metal layer 602 is deposited in the trench 210 and planarized by the CMP technique (FIG. 6).

Step 120: A photoresist layer 702 is deposited and patterned (FIG. 7).

Step 122: The metal layer 602 corresponding to ends of the active region is etched to form multiple conductive lines (FIG. 7).

Step 124: The photoresist layer 702 is removed and the metal layer 602 (the multiple conductive lines) is etched back to form underground bit lines (UGBL) 902 or underground conductive lines (FIG. 8).

Step 126: An oxide-2 layer 1002 is deposited in the trench 210 and planarized by the CMP technique (FIG. 9).

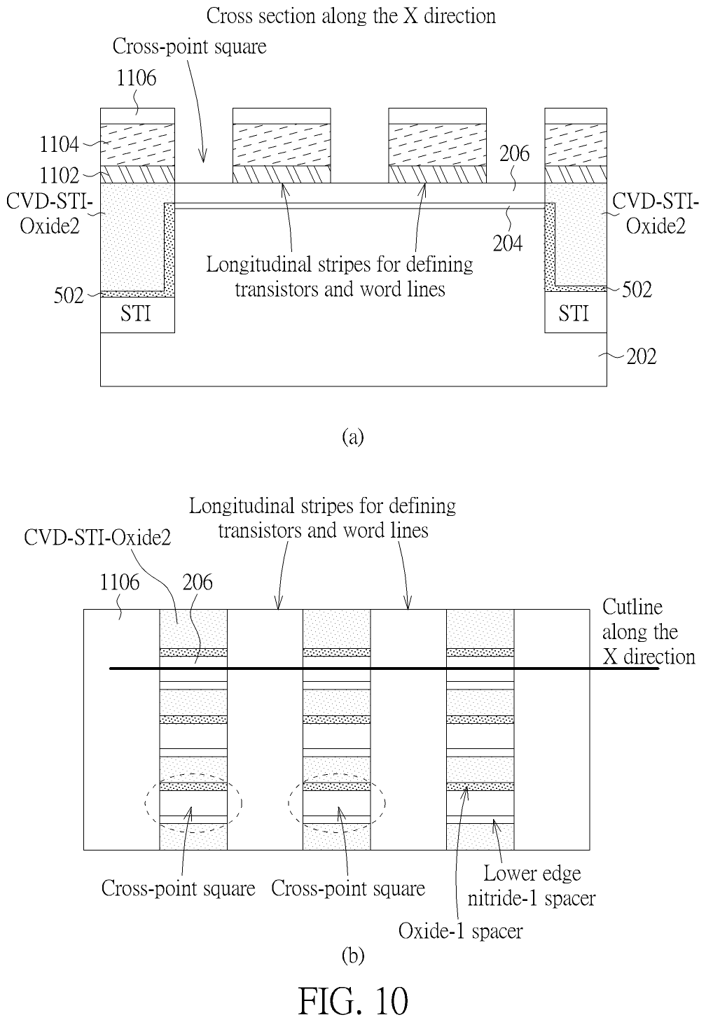

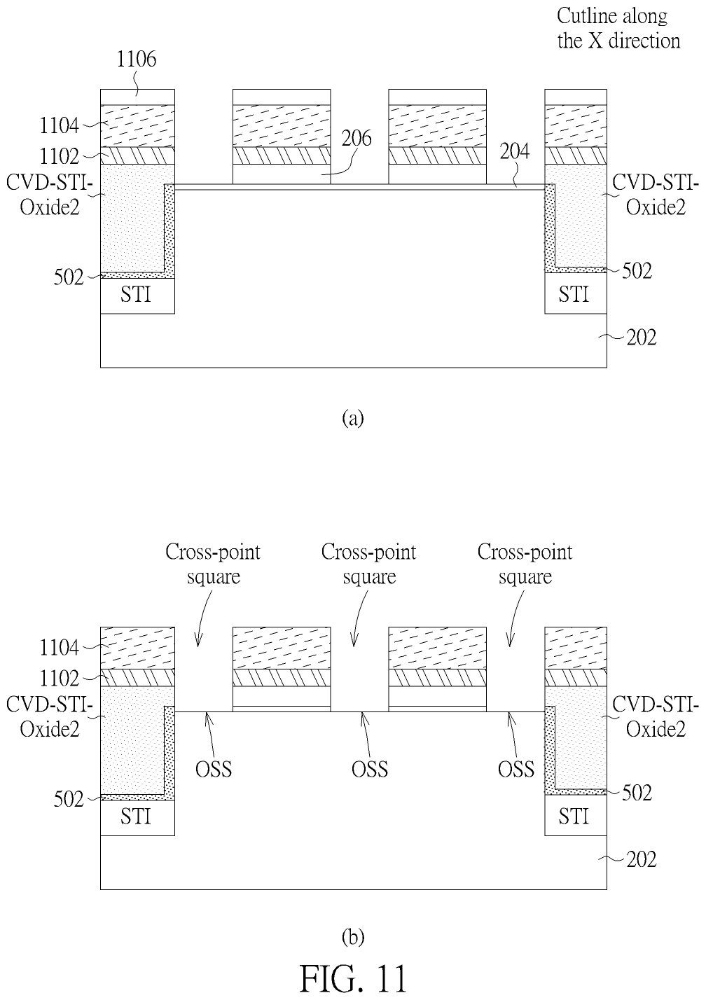

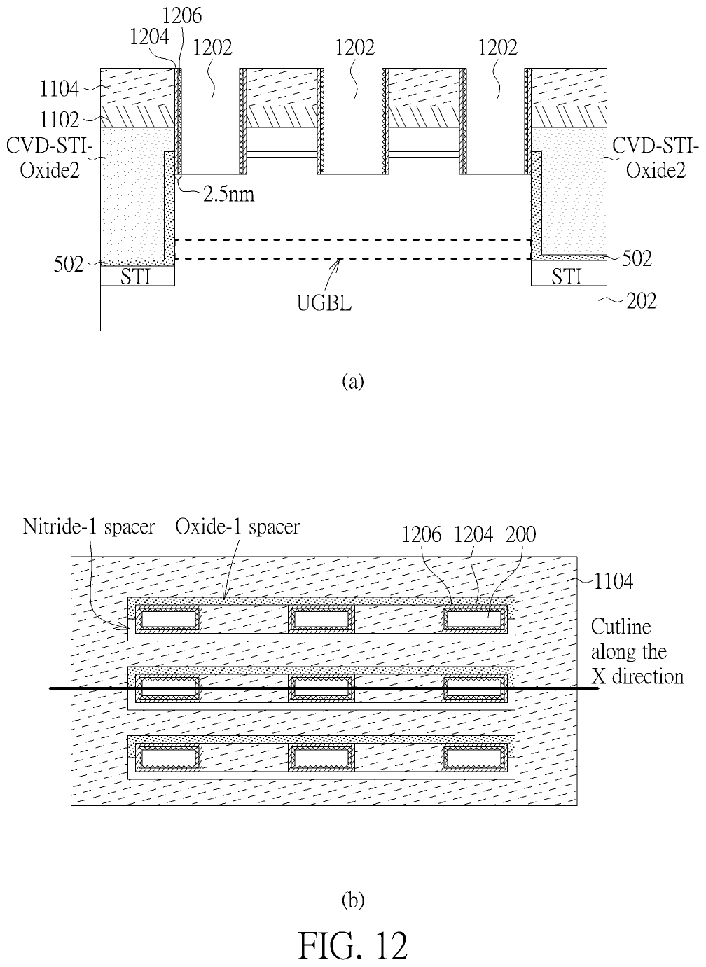

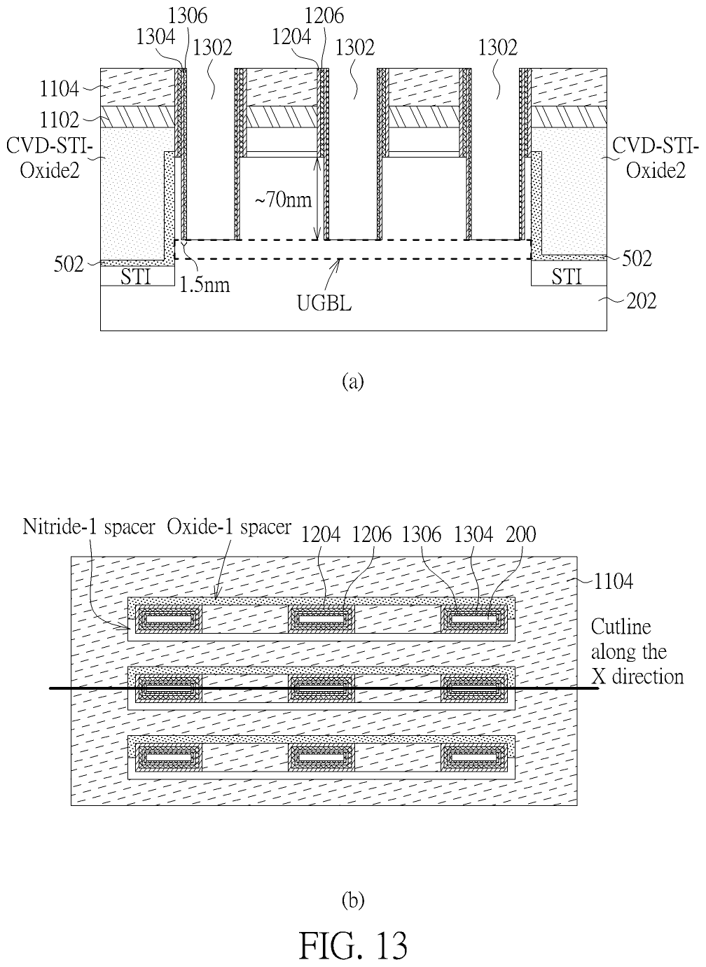

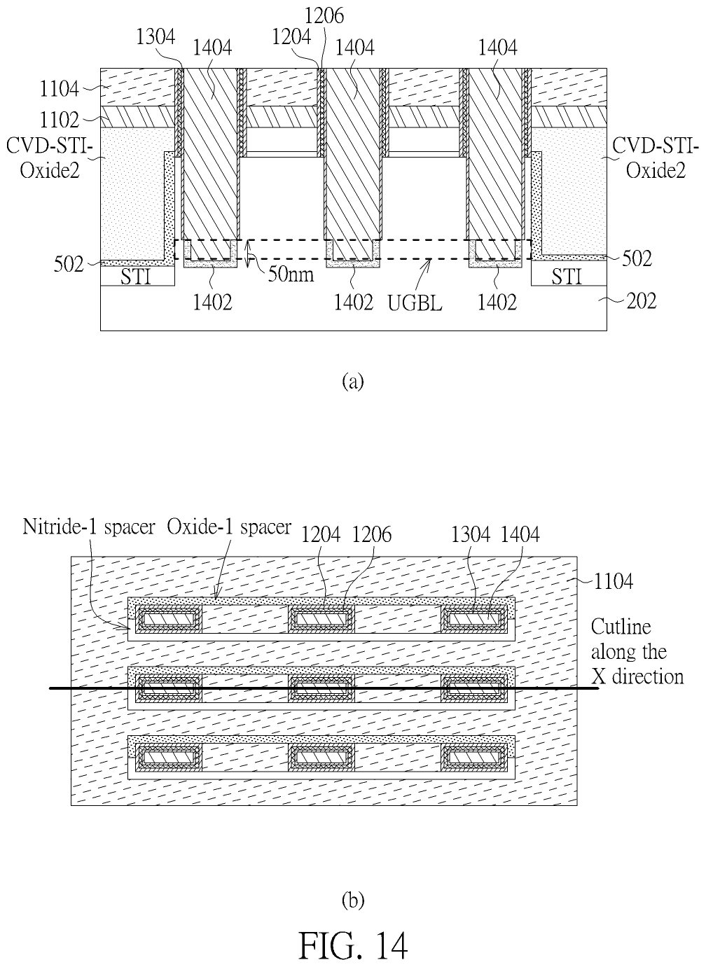

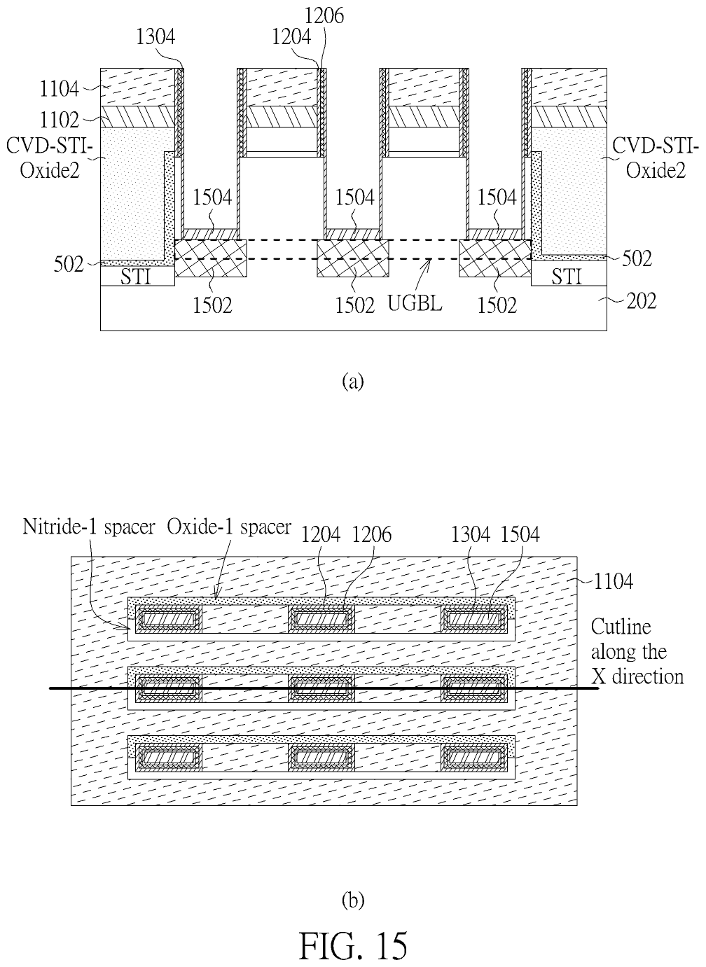

Please refer to FIG. 1E and FIG. 10, FIG. 11, FIG. 12, FIG. 13, FIG. 14, FIG. 15. Step 30 could include:

Step 128: A thick oxide-3 layer 1102, a thick nitride-2 layer 1104, and a patterned photoresist layer 1106 are deposited, and then unnecessary parts of the oxide-3 layer 1102, the nitride-2 layer 1104 are etched or removed (FIG. 10).

Step 130: The patterned photoresist layer 1106, the pad-nitride layer 206, and the pad-oxide layer 204 are removed, and the OSS could be revealed (FIG. 11).

Step 132: Dig the revealed OSS to create concave 1202 (FIG. 12).

Step 134: Form an oxide spacer-1 1204 and then a nitride spacer-1 1206 along edges of the concave 1202 (FIG. 12).

Step 136: Remove the exposed silicon areas in the concave 1202 in a straight vertical shape to form trench hole 1302 (FIG. 13).

Step 138: Form an oxide spacer-2 1304 and then a nitride spacer-2 1306 along edges of the trench hole 1302 (FIG. 13).

Step 140: Remove the exposed silicon areas in the trench hole 1302 and grow thermal oxide 1402 (FIG. 14).

Step 142: Remove the lower nitride-1 spacer on the sidewall of the underground bit line to reveal the sidewall of the underground bit line, and deposit in-situ doped n+ polysilicon 1404 in the trench to connect the revealed sidewall the underground bitline (FIG. 14).

Step 144: Remove the in-situ doped n+ polysilicon 1404 and the thermal oxide 1402 (FIG. 15).

Step 146: Use the selective epitaxy growth (SEG) technique to grow the (N+) drain region 1502 (FIG. 15).

Step 148: Grow thermally an oxide plug 1504 in the trench region (FIG. 15).

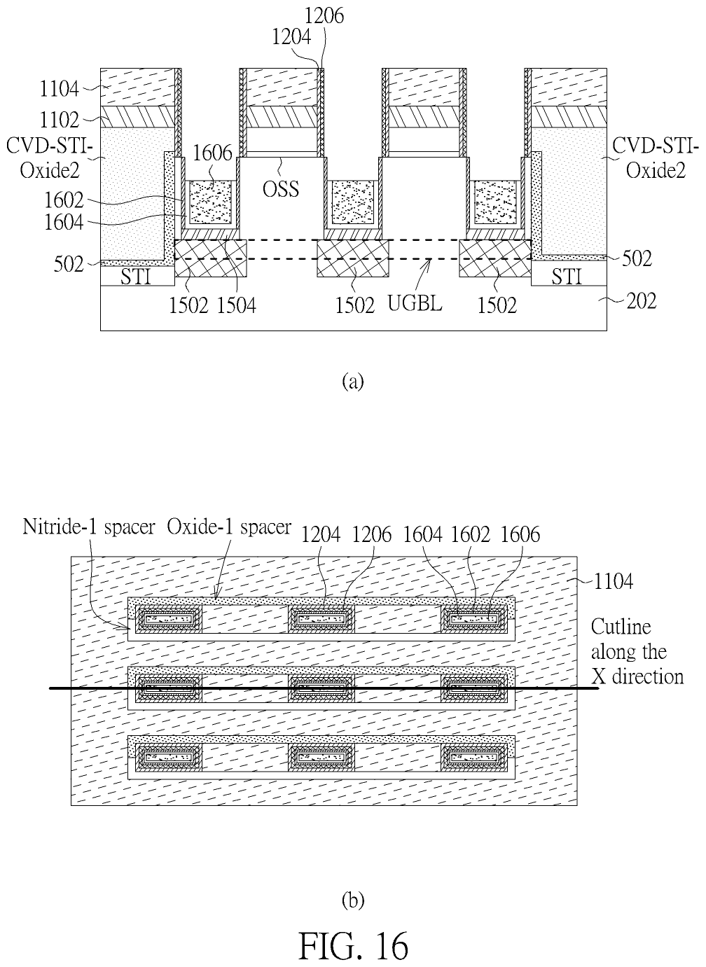

Please refer to FIG. 1F and FIG. 16. Step 35 could include:

Step 150: Remove the oxide spacer-2 1304 (FIG. 16).

Step 152: Thermally grow a thermal oxide 1602 (FIG. 16).

Step 154: Deposit a TiN layer 1604 and a Tungsten layer 1606, and then etch back the TiN layer 1604 and the Tungsten layer 1606 (FIG. 16).

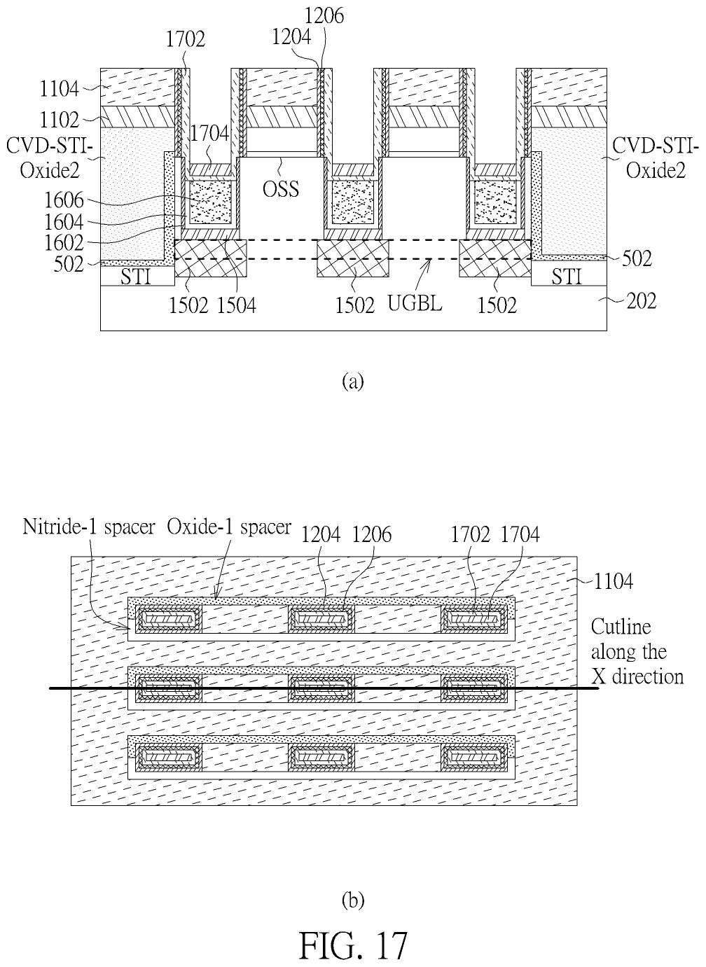

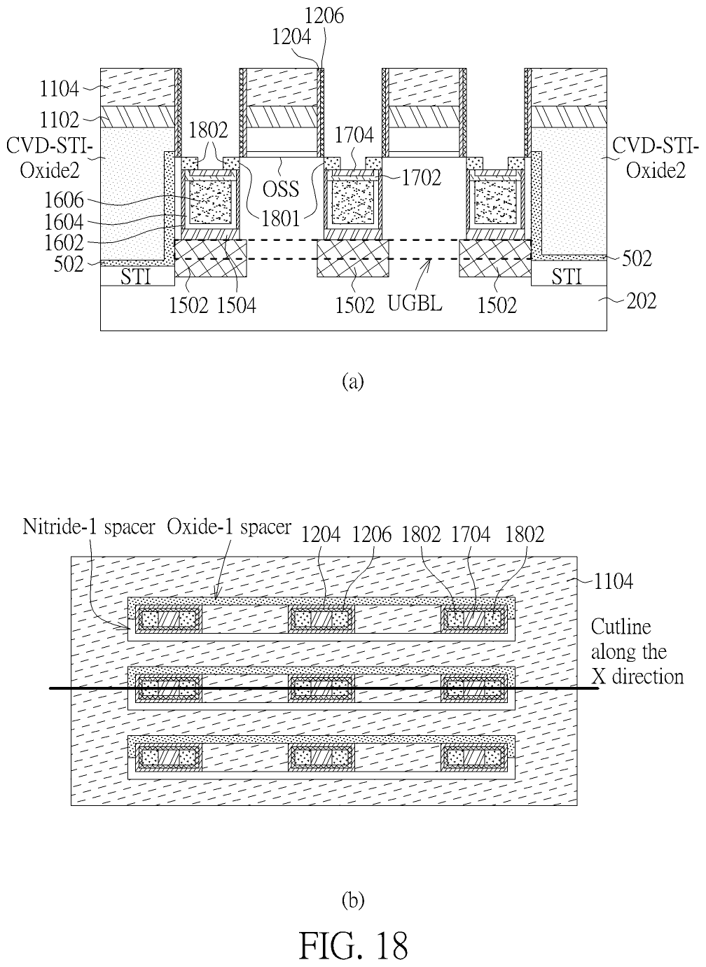

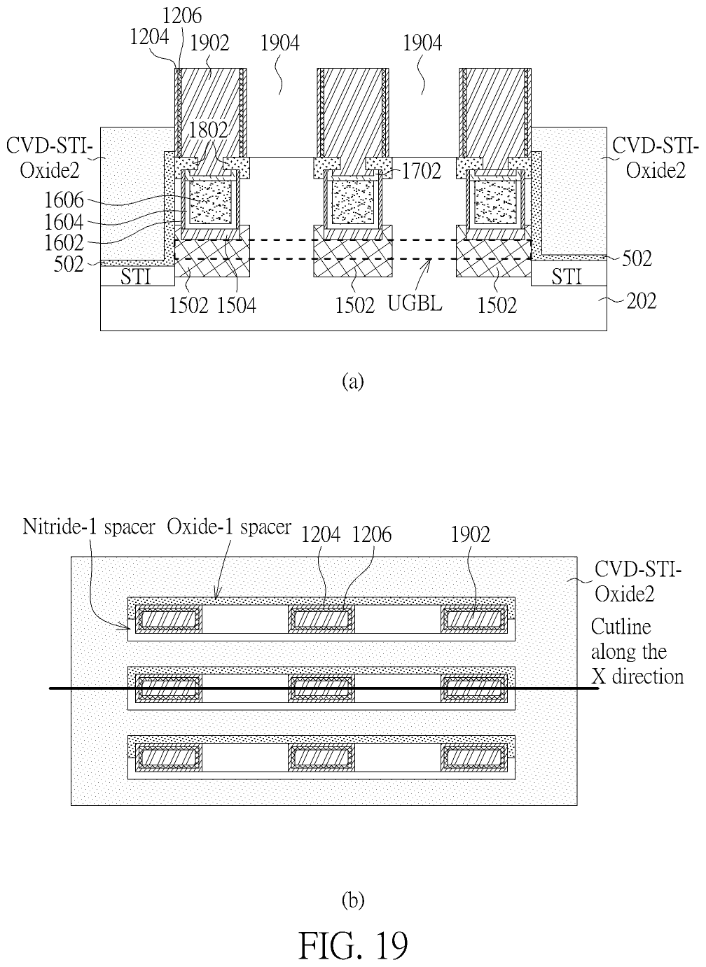

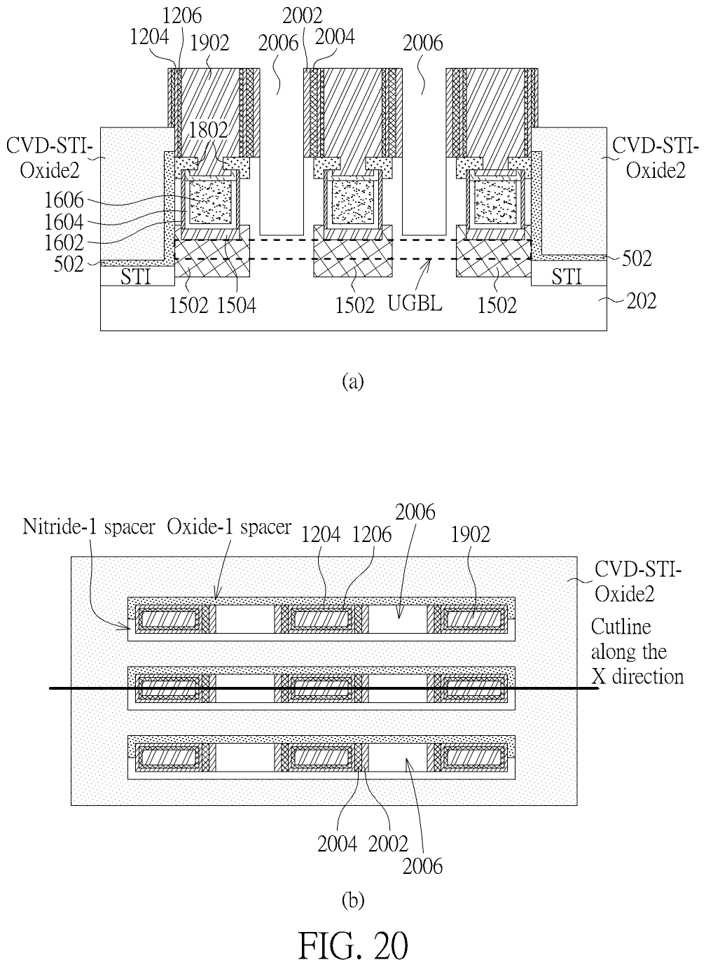

Please refer to FIG. 1G and FIG. 17, FIG. 18, FIG. 19, FIG. 20. Step 40 could include:

Step 156: Deposit a nitride layer 1702 and then deposit and etch down an oxide layer 1704 (FIG. 17).

Step 158: Etch the nitride layer 1702 and portion of the oxide layer 1704 to expose silicon sidewalls 1801 close to and under the OSS, and use the SEG technique to grow n-type LDD (lightly doped drain) 1802 through the exposed sidewalls 1801 of the silicon (FIG. 18).

Step 160: Deposit an oxide layer 1902 and use the CMP technology to make a planar surface of the oxide layer 1902 be leveled up to the surface of the nitride-2 layer 1104 (FIG. 19, also refer to FIG. 18).

Step 162: Use RTA (rapid thermal anneal) to create out-diffuse regions for previously grown source and drain regions (FIG. 19).

Step 164: Etch away the oxide-3 layer 1102, the nitride-2 layer 1104, the pad-nitride layer 206, and the pad-oxide layer 204 to form concave 1904 next to the oxide layer 1902 and reveals the OSS (FIG. 19, also refer to FIG. 18).

Step 166: Form an oxide spacer-3 2002 and a nitride spacer-3 2004 (FIG. 20).

Step 168: Based on the oxide spacer-3 2002 and the nitride spacer-3 2004, anisotropic etch the reveal silicon to form deep trench 2006 (FIG. 20).

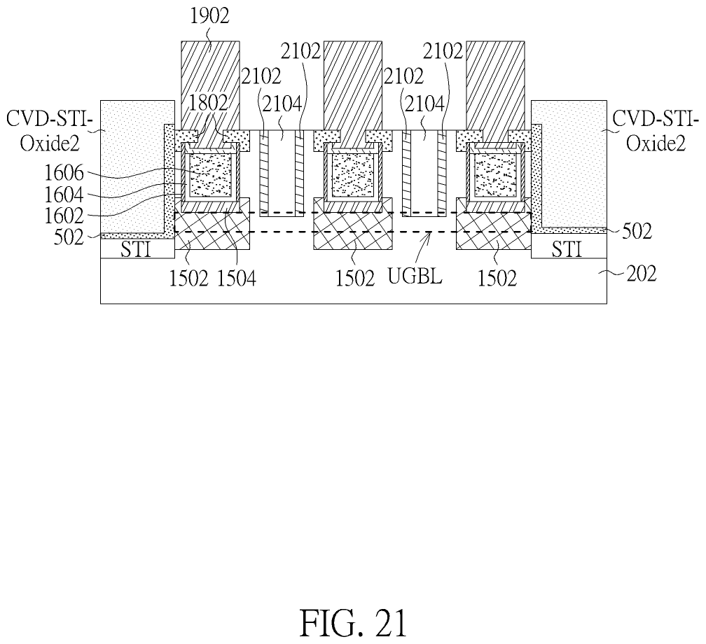

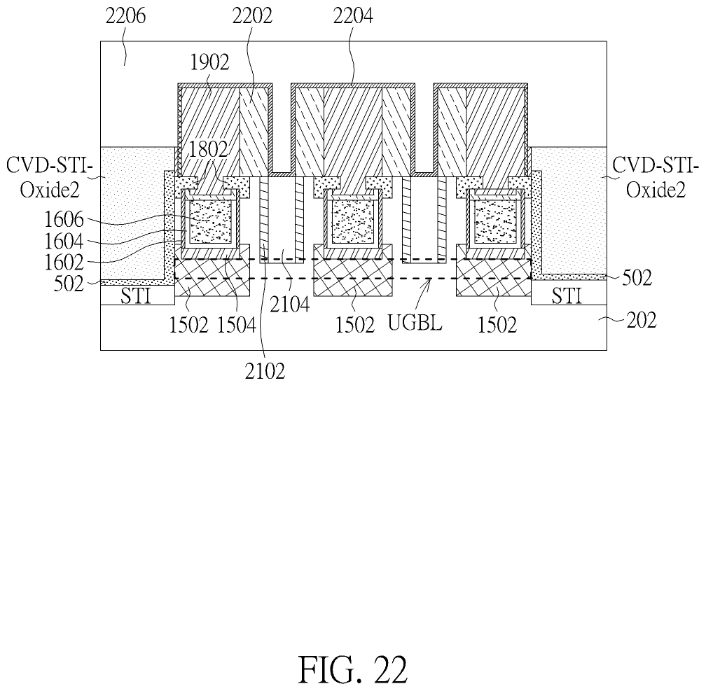

Please refer to FIG. 1H and FIG. 21, FIG. 22. Step 45 could include:

Step 170: Grow thin in-situ doped p-type silicon layer 2102 (FIG. 21).

Step 172: Grow thermal oxide 2104 to fill completely the trench (FIG. 21).

Step 174: Remove the oxide spacer-3 2002, the nitride spacer-3 2004, the oxide spacer-1 1204 and the nitride spacer-1 1206; and then use the SEG technique to grow the vertical layer 2202 (FIG. 22).

Step 176: Form high-k dielectric layer 2204 over the vertical layer 2202 as the storage-node insulator, and then form a conductive layer (such as, SiₓGe₁₋ₓ) 2206 as the capacitor counter-electrode (FIG. 22).

Detailed description of the aforesaid manufacturing method is as follows. Start with a p-type silicon wafer (i.e. the p-type substrate 202), wherein in another embodiment of the present invention, the present invention could start with a p-type well in a triple-well structure of a CMOS (complementary metal oxide semiconductor) process so that the cell substrate can be biased at a negative voltage.

In Step 102, as shown in FIG. 2(a), the pad-oxide layer 204 is thermally grown above the planar surface 208 (i.e. named as a horizontal silicon surface (HSS) or original silicon surface (OSS) if the substrate is silicon substrate, hereinafter the original silicon surface or OSS is used as example), and then the pad-nitride layer 206 is deposited above the pad-oxide layer 204.

In Step 104, the active regions of the TOB-cell array can be defined by a photolithographic technique, wherein as shown in FIG. 2 (a), use the pad-nitride layer 206 as a mask so that the active region of the TOB-cell array corresponds to the pad-oxide layer 204 and the pad-nitride layer 206, and the planar surface 208 outside the pad-nitride layer 206 is exposed accordingly. Because the planar surface 208 outside the pad-nitride layer 206 is exposed, the parts of the silicon material corresponding to the planar surface 208 outside the pad-nitride layer 206 can be removed by an anisotropic etching technique to create the trench (or concave) 210, wherein for example, the trench 210 can be 300-350 nm deep below the OSS.

In Step 106, the oxide layer 214 is deposited to fully fill the trench 210 and then the oxide layer 214 is etched back such that the STI inside the trench 210 is formed below the OSS. In addition, FIG. 2 (b) is a top view corresponding to FIG. 2(a), wherein FIG. 2 (a) is a cross-section view along an X direction shown in FIG. 2(b).

In Step 108, as shown in FIG. 3(a), the nitride-1 layer is deposited and etched back by the anisotropic etching so as to create the nitride-1 spacers along both edges (i.e. an upper edge and a lower edge) of the trench 210. In another embodiment of the present invention, the nitride-1 spacers could be replaced with SiOCN as one side spacer.

In Step 110, as shown in FIG. 3(a), the SOD 304 is deposited in the trench 210 above the STI to fill the trench 210. Then, the SOD 304 is planarized by the CMP technique to make a top of the SOD 304 as high as a top of the pad-nitride layer 206.

In Step 112, as shown in FIG. 3(a), lower edge nitride-1 spacers of the nitride-1 spacers along the lower edge of the trench 210 are protected by the photoresist layer 306, but upper edge nitride-1 spacers of the nitride-1 spacers along the upper edge of the trench 210 are unprotected. That is, after the photoresist layer 306 is deposited above the SOD 304 and the pad-nitride layer 206, because a part of the photoresist layer 306 above the upper edge nitride-1 spacer is removed but a part of the photoresist layer 306 above the lower edge nitride-1 spacer is kept, the lower edge nitride-1 spacer can be protected and the upper edge nitride-1 spacer can be removed later. In addition, FIG. 3(b) is a top view corresponding to FIG. 3(a), wherein FIG. 3 (a) is a cross-section view along a cut line of a Y direction shown in FIG. 3(b). In Step 114, as shown in FIG. 4, the upper edge nitride-1 spacer and the SOD 304 not covered by the photoresist layer 306 are etched away by an isotropic etching process.

In Step 116, as shown in FIG. 5, both the photoresist layer 306 and the SOD 304 are stripped off, wherein the SOD 304 has much higher etching rate than that of thermal oxide and some deposited oxide. Then, the oxide-1 layer 502 is grown thermally to form oxide-1 spacer to cover the upper edge of the trench 210, wherein the oxide-1 layer 502 is not grown over the pad-nitride layer 206. As shown in FIG. 5, Step 116 results in asymmetric spacers (the lower edge nitride-1 spacer and the oxide-1 spacer) on two symmetrical edges (the upper edge and the lower edge) of the trench 210, respectively. For example, a thickness of the oxide-1 spacer is about 1 nm and a thickness of the lower edge nitride-1 spacer is about 1 nm-1.5 nm. A structure of the asymmetric spacers (shown in FIG. 5) and the above-mentioned related steps are key feature of the present invention, which is named as asymmetric spacers on two symmetrical edges of a trench or a canal (ASoSE).

In Step 118, as shown in FIG. 6, the metal layer 602 (or a conductive material (e.g. doped polysilicon) which needs to sustain the subsequent processing conditions) is deposited to fully fill the trench 210 and planarized by the CMP technique to make a top of the metal layer 602 be leveled off equally with the top of the pad-nitride layer 206 (shown in FIG. 6). In addition, in one embodiment of the present invention, the metal layer 602 can be a thin TiN plus Tungsten. In addition, FIG. 4, FIG. 5, and FIG. 6 are cross-section views along the cut line of the Y direction shown in FIG. 3(b).

In Step 120, as shown in FIG. 7, the photoresist layer 702 is deposited cover both the lower edge nitride-1 spacer and the oxide-1 spacer but to expose two edges of the lower edge nitride-1 spacer and the oxide-1 spacer corresponding to the ends of the active region. Next, In Step 122, as shown in FIG. 7, the metal layer 602 corresponding to the ends of the active region is etched to separate the multiple conductive lines (i.e. the metal layer 602).

In Step 124, after the photoresist layer 702 is removed, the metal layer 602 is etched back but left only a reasonable thickness inside the trench 210 to form the conductive line or the underground bit line (UGBL) 902, wherein a top of the underground bit line 902 is much lower than the OSS (e.g., a thickness of the underground bit line 902 is about 40 nm). In addition, as shown in FIG. 8 (a), the underground bit line (UGBL) 902 is on the top of the STI and both sidewalls of the underground bit line (UGBL) 902 are bounded by the asymmetric spacers, that is, the lower edge nitride-1 spacer and the oxide-1 spacer, respectively. In addition, FIG. 8(a) is a cross-section view along the Y direction shown in FIG. 8(b).

In Step 126, as shown in FIG. 9 (the cross-section view along the Y direction shown in FIG. 8(b)), the oxide-2 layer 1002 (called as CVD-STI-oxide2) needs to be thick enough to fill the trench 210 over the underground bit line 902, and then the oxide-2 layer 1002 is polished back to reserve some part which is leveled as high as the top of the pad-nitride layer 206, and covers both the lower edge nitride-1 spacer and the oxide-1 spacer. As shown in FIG. 9, Step 126 can make the underground bit line 902 (i.e. an interconnection line) embedded and bounded by all insulators (i.e. an isolation region) inside the trench 210 (and later the underground bit line 902 will be connected to drain regions of access transistors of the TOB-cell array) which is named as underground bit-lines (UGBL) surrounded by insulators. The UGBL is another key feature of the present invention.

The following descriptions introduce how to form both the access transistors and word lines of the TOB-cell (1T1C cell) array, and the word lines connect all associated gate structures of the access transistors simultaneously by a self-alignment method and thus both the gate structures and the word lines are connected as one body of metal such as Tungsten (W).

In Step 128, as shown in FIG. 10 (a), first, the thick oxide-3 layer 1102, the nitride-2 layer 1104, and the patterned photoresist 1106 are deposited. Then, the unnecessary parts of the oxide-3 layer 1102 and the nitride-2 layer 1104 are removed by using etching technique. A transistor/word line pattern will be defined by the composite layers of the oxide-3 layer 1102 and the nitride-2 layer 1104, wherein the composite layers of the oxide-3 layer 1102 and the nitride-2 layer 1104 include multiple stripes in a direction perpendicular to a direction of the active region, and for example, a width of an individual transistor/word line pattern can be 1.5˜2F if the TOB-cell is designed under the minimum feature size F˜6 nm. Therefore, as shown in FIG. 10(a) and FIG. 10(b), longitudinal (the Y direction) stripes (the oxide-3 layer 1102 and the nitride-2 layer 1104) for defining the access transistors and the word lines are formed, wherein the active region is located at cross-point square between the longitudinal stripes, wherein FIG. 10(a) is a cross-section view along the X direction shown in FIG. 10(b).

As shown in FIG. 10(b), a top view reveals fabric-like checkerboard patterns with the longitudinal stripes of the oxide-3 layer 1102 and the nitride-2 layer 1104 over the pad-nitride layer 206 and the pad-oxide layer 204, and both the active region and the STI are in a horizontal direction (i.e. the X direction shown in FIG. 10(b)). The active region allows the access transistors to be made by a kind of a self-alignment technique. Such a checkerboard fabric proposal for making self-aligned structures of making the gate structures of the access transistors and the word lines in one processing step is another key feature of the present invention.

In Step 130, as shown in FIG. 11 (a), the photoresist layer 1106 is kept so as to the pad-nitride layer 206 is etched but the pad-oxide layer 204 is retained, and as shown in FIG. 11(b), both the photoresist layer 1106 and the pad-oxide layer 204 are removed by the etching technique (e.g. the reactive ion etching (RIE) process). As a result, the planar surface 208 (i.e. the OSS) is exposed at the cross-point squares (shown in FIG. 11(b)) corresponding to the active region. In addition, FIG. 11(a) and FIG. 11(b) are the cross-section views along the X direction shown in FIG. 10(b).

In Step 132, as shown in FIG. 12(a), the OSS exposed at the cross-point squares is dug through the anisotropic etching technique to create the concave 1202, wherein the concave 1202 later becomes a region containing the gate structure of the access transistor and can be extended down to a certain distance below the OSS (e.g. below the OSS around 6-8 nm depth). In addition, use the anisotropic etching technique to dig through the STI (e.g. ˜5 nm depth) so as to create a canal-shape concave (along the Y direction shown in FIG. 8 (b)) for later local wordline interconnects, wherein a depth (e.g. ˜5 nm) of the canal-shape concave is shallower than a depth (e.g. ˜6 nm) of the concave 1202. In addition, FIG. 12(a) is the cross-section view along the X direction shown in FIG. 12(b).

In Step 134, as shown in FIG. 12(a), form the oxide spacer-1 1204 and then the nitride spacer-1 1206 along edges of the concave 1202. To take as an example, a sum of a width of the oxide spacer-1 1204 and a width of the nitride spacer-1 1206 can be ˜2.5 nm which is critical since the active silicon material below the oxide spacer-1 1204 and the nitride spacer-1 1206 will be used as later formation of the channel regions of the access transistor.

In Step 136, as shown in FIG. 13(a), by taking the nitride spacer-1 1206 as a mask, use the anisotropic etching technique to remove the exposed silicon areas in a straight vertical shape to form the trench hole 1302 (e.g. a depth of the trench hole 1302 is ˜70 nm). In addition, use the anisotropic etching technique to dig through the STI (e.g. ˜50 nm depth) so as to create canal-shape concave (along the Y direction shown in FIG. 8(b)) for later local wordline interconnects.

In Step 138, as shown in FIG. 13(a), form the oxide spacer-2 1304 and then the nitride spacer-2 1306 along the edges of the trench hole 1302. To take as an example, a sum of a width of the oxide spacer-2 1304 and a width of the nitride spacer-2 1306 can be ˜1.5 nm. In addition, FIG. 13(a) is the cross-section view along the X direction shown in FIG. 13(b).

In Step 140, as shown in FIG. 14(a), by using the nitride spacer-2 1306 as a mask, adopt the anisotropic etching technique to further remove the exposed silicon in the trench hole 1302 to form a trench region, wherein for example, the trench region has a depth ˜50 nm. Then, grow the thermal oxide 1402 surrounding trench walls and a bottom of the trench region. In one example, the trench region in the active region will be next to the underground bit line (UGBL) which is located within the STI region surrounding the active region, as shown in FIG. 14(a).

In Step 142, as shown in FIG. 14 (a), remove the lower nitride-1 spacer on the sidewall of the underground bit line (see FIG. 9) to reveal the sidewall, meanwhile the nitride spacer-2 1306 will be removed as well. Then, as shown in FIG. 14(a), deposit the in-situ doped n+ polysilicon 1404 to fill the trench region. In one example, the in-situ doped n+ polysilicon 1404 will connect the revealed sidewall of UGBL. In addition, FIG. 14(a) is the cross-section view along the X direction shown in FIG. 14(b).

In Step 144, as shown in FIG. 15(a), use the isotropic etching technique to remove the in-situ doped n+ polysilicon 1404 and the thermal oxide 1402 for following formation of the drain region of the access transistor. In this step, portion of the in-situ doped n+ polysilicon 1404 connected to the revealed sidewall of UGBL will be left due to the protection of the spacers (such as spacer 1204, 1206, or 1304) and plays a role of underground bitline connector (UBC).

In Step 146, as shown in FIG. 15(a), use the selective epitaxy growth (SEG) technique to grow a thin layer (e.g. ˜10 nm) of n+ in-situ doped polysilicon layer to form the (N+) drain region 1502 over the underground bitline connector (UBC) which is made of in-situ doped n+ polysilicon to guarantee that the n+ drain region 1502 and the UBC could be well connected.

In another embodiment, in Step 142, as shown in FIG. 14(a), first remove the lower nitride-1 spacer on the sidewall of the underground bit line (see FIG. 9) to reveal the sidewall. Then without depositing the in-situ doped n+ polysilicon 1404 to fill the trench region, just use the etching technique to remove the thermal oxide 1402 to expose sidewalls and bottom surface of the silicon which are the bases for the selective epitaxy growth (SEG). Thereafter, use SEG technique to grow a thin layer (e.g. ˜10 nm) of n+ in-situ doped polysilicon layer to form the (N+) drain region 1502 which then directly connects the revealed sidewall the underground bitline. Since the (N+) drain region 1502 is automatically connected to sidewall of the underground bitline, it is unnecessary to form another connecting plug between the underground bitline and the (N+) drain region 1502.

In Step 148, as shown in FIG. 15(a), then grow thermally the oxide plug 1504 in the trench region. In addition, FIG. 15(a) is the cross-section view along the X direction shown in FIG. 15(b).

Next, described below is to form the gate structure of the access transistor and the local wordline. In Step 150, as shown in FIG. 16(a), then remove the oxide spacer-2 1304 so that the silicon area for the channel of the access transistor is exposed.

In Step 152, as shown in FIG. 16(a), thermally grow the thermal oxide 1602 over the exposed silicon area, which forms dielectric layer of the access transistor (can be any other high-K composite gate insulator).

In Step 154, as shown in FIG. 16(a), then deposit the TiN layer 1604 and then the Tungsten layer 1606 to form both the gate structure and the local wordline which are automatically connected. Then, the TiN layer 1604 and the Tungsten layer 1606 are etched back until top surfaces of the TiN layer 1604/the Tungsten layer 1606 are below the OSS (e.g. ˜5 nm). In addition, FIG. 16(a) is the cross-section view along the X direction shown in FIG. 16(b).

In Step 156, as shown in FIG. 17(a), deposit the nitride layer 1702 (which protects the TiN layer 1604/the Tungsten layer 1606 without being deteriorated due to being touched by any oxide material), and then deposit the oxide layer 1704. Then, use the etch down method to remove portion of the oxide layer 1704, so that the composite structure having capped layers of the oxide layer 1704 and the nitride layer 1702 over both the gate structure and the local wordline is reserved. In addition, FIG. 17(a) is the cross-section view along the X direction shown in FIG. 17(b).

In Step 158, as shown in FIG. 18 (a), then etch the nitride layer 1702 and the portion of the oxide layer 1704 to expose the silicon sidewalls 1801 close to and under the OSS. Then, use the SEG technique to grow the n-type LDD 1802 with single-crystalline silicon through the expose sidewalls 1801. In addition, FIG. 18(a) is the cross-section view along the X direction shown in FIG. 18(b).

In Step 160, as shown in FIG. 19(a), first deposit the oxide layer 1902 to fill in the trench above the gate structure, and use the CMP technology to make the planar surface of the oxide layer 1902 be leveled up to the surface of the nitride-2 layer 1104.

In Step 162, as shown in FIG. 19(a), then use RTA to create out-diffuse regions for the n-type LDD 1802 and the (N+) drain region 1502. In one example, the out-diffused regions of the n-type LDD 1802 will be substantially aligned with the top surface of the TiN layer 1604 or the Tungsten layer 1606, and the out-diffused regions of the (N+) drain region 1502 will be substantially aligned with the bottom surface of the TiN layer 1604 or the Tungsten layer 1606.

In Step 164, as shown in FIG. 19(a), further etch away the oxide-3 layer 1102, the nitride-2 layer 1104, the pad-nitride layer 206, and the pad-oxide layer 204 between the oxide layers 1902 to form the concave 1904 and reveals the OSS. In addition, FIG. 19(a) is the cross-section view along the X direction shown in FIG. 19(b).

In Step 166, as shown in FIG. 20(a), then form the oxide spacer-3 2002 and the nitride spacer-3 2004 on the sidewalls of the concave 1904, and the thickness of the oxide spacer-3 2002 and the nitride spacer-3 2004 could be thick enough to cover the out-diffuse regions of the n-type LDD 1802 and the (N+) drain region 1502.

In Step 168, as shown in FIG. 20(a), based on the oxide spacer-3 2002 and the nitride spacer-3 2004, anisotropic etch the reveal silicon to form the deep trench 2006. In addition, FIG. 20(a) is the cross-section view along the X direction shown in FIG. 20(b).

In Step 170, as shown in FIG. 21, then use the SEG (selective epitaxy growth) technique to grow the in-situ doped p-type silicon layer 2102 (for example, the in-situ doped p-type silicon layer 2102 can be in-situ heavily doped p-type single-crystalline silicon layer), wherein the doping type (i.e. p-type) of the in-situ doped p-type silicon layer 2102 is different from that of the drain/source regions. The purpose of Step 170 is to form an extra p-type connection to the p-type body of the access transistor, which allows a negative substrate voltage (e.g. −0.3 V or so) to provide a bias to the p-type substrate 202 of the access transistor (this practice is well adopted for the TOB-cell to avoid any noise occurring on p-n junctions of the access transistor to cause any extra leakage of the capacitor charges).

In Step 172, as shown in FIG. 21, grow the thermal oxide 2104 to fill completely the trench with some extra overflow and use the isotropic etching technique to remove the thermal oxide 2104 overflow so that the residue oxide is leveled up to above the OSS. Then, remove the oxide spacer-3 2002, the nitride spacer-3 2004, the oxide spacer-1 1204, and the nitride spacer-1 1206 so that the OSS area reserved for making the source region of the access transistor are all exposed.

In Step 174, as shown in FIG. 22, then use the SEG technique to grow the vertical layer 2202 of selective epi material which is in-situ doped by n+(e.g. Phosphorus) over the exposed source region. The key feature is that these epi grown pillars (i.e. the vertical layer 2202) over the two source regions (also over the in-situ doped p-type silicon layer 2102) can act as storage nodes/electrodes of the storage capacitor. These pillars are self-constructed vertically just like having two legs grown for the storage capacitor.

In Step 176, as shown in FIG. 22, then a thin layer of the high-k dielectric layer 2204 can be formed over the vertical layer 2202 as the storage-node insulator. Then form a thin conductive layer (such as, SiₓGe₁₋ₓ with Boron dopant) 2206 as the capacitor counter-electrode. In addition, FIG. 21 and FIG. 22 are the cross-section views along the X direction shown in FIG. 20(b).

In summary, the TOB-cell (transistor-over-bitline DRAM cell) is disclosed in the present invention. The TOB-cell includes a capacitor over an access transistor which is then over underground bit lines. The access transistor of the TOB-cell is a vertical transistor with two separate vertical channels for enhancing current connection. The (N+) drain region 1502 is automatically, either directly or indirectly, connected to sidewall of the underground bitline, and the storage nodes of the storage capacitor (i.e., the epi grown pillars or the vertical layer 2202) are self-constructed over the source region which includes two separate sub-regions. Thus, the complexities of arranging the word lines, bit lines and storage capacitors on their geometric and topographic structures and connections to the gates, sources and drains of the access transistors are solved, and the TOB-cell can be shrunk to a cell area of 4.5×2.5 F (or 5×2.5 F) where the minimum feature size F is scalable to a range of ˜6 nm.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A semiconductor device structure comprising:
a semiconductor substrate with an original surface;
an active region within the semiconductor substrate, wherein the active region comprises a transistor, the transistor comprises a gate structure with a bottom surface under the original surface, a first conductive region, and a second conductive region;
a STI region surrounding the active region; and
an interconnection layer extended beyond the transistor and electrically coupled to the transistor at a connection position under the gate structure.

2. The semiconductor device structure of claim 1, wherein the interconnection layer is disposed within the STI region and under the original surface, and the interconnection layer is isolated from the semiconductor substrate.

3. The semiconductor device structure of claim 1, wherein the second conductive region comprises two sub-regions located on two sides of the gate structure respectively, and the first conductive region is lower than the second conductive region.

4. The semiconductor device structure of claim 3, the transistor further comprising two vertical channel regions separate from each other, wherein the first conductive region is electrically connected to the two sub-regions of the second conductive region through the two vertical channel region.

5. The semiconductor device structure of claim 4, further comprising a highly doped semiconductor region next to one of the two vertical channel regions, the highly doped semiconductor region extends downward from the original surface and a dopant type of the highly doped semiconductor region is different from that of the first conductive region.

6. The semiconductor device structure of claim 1, wherein the interconnection layer is coupled to the first conductive region of the transistor at the connection position through a connection contact which is a highly doped semiconductor plug, or the interconnection layer is directly coupled to the first conductive region of the transistor at the connection position.

7. The semiconductor device structure of claim 1, further comprising a capacitor electrically connected to the second conductive region, and the interconnection layer is a bitline electrically connected to the first conductive region.

8. The semiconductor device structure of claim 7, further comprising a wordline electrically connected to the gate structure, and the wordline penetrates through the second conductive region.

9. The semiconductor device structure of claim 1, further comprising a dielectric plug between the gate structure and the first conductive region.

10. A semiconductor device structure comprising:
a semiconductor substrate with a semiconductor surface;
a first active region, a second active region, and a shallow trench isolation (STI) region between the first active region and the second active region;
a transistor formed based on the first active region and comprising a gate structure, a first conductive region, and a second conductive region; and
an interconnection layer within the STI region and electrically coupled to the first conductive region of the transistor, wherein the first conductive region is below the gate structure of the transistor.

11. The semiconductor device structure of claim 10, wherein a side surface of the interconnection layer abuts against a side surface of a connection contact which directly connects the first conductive region of the transistor.

12. The semiconductor device structure of claim 10, wherein the interconnection layer extends along the STI region and is positioned under the semiconductor surface.

13. The semiconductor device structure of claim 12, wherein the STI region comprises a first spacer contacted to the first active region and a second spacer contacted to the second active region, and a material of the first spacer is different from that of the second spacer.

14. The semiconductor device structure of claim 10, wherein a side surface of the interconnection layer abuts against a side surface of the first conductive region of the transistor.

15. The semiconductor device structure of claim 10, further comprising a capacitor electrically connected to the second conductive region, and the interconnection layer is a bitline electrically connected to the first conductive region.

16. The semiconductor device structure of claim 15, further comprising a wordline electrically connected to the gate structure, wherein the second conductive region comprises two sub-regions located on two sides of the gate structure, and the wordline penetrates through the two sub-regions of the second conductive region.

17. A semiconductor device structure comprising:
a semiconductor substrate with a semiconductor surface;
an active region, and a STI region surrounding the active region;
a transistor within the active region, and the transistor comprising a gate structure, a first conductive region, and a second conductive region; and
an interconnection layer within the STI region and electrically coupled to the first conductive region of the transistor, wherein the second conductive region is above the first conductive region and comprises two sub-regions located on two sides of the gate structure respectively.

18. The semiconductor device structure of claim 17, wherein the transistor further comprising two vertical channel regions separate from each other, wherein the first conductive region is electrically connected to the two sub-regions of the second conductive region through the two vertical channel regions.

19. The semiconductor device structure of claim 17, further comprising a capacitor electrically connected to each of the two sub-regions of the second conductive region of the transistor.

20. The semiconductor device structure of claim 19, wherein the capacitor comprises two electrode pillars connected to the two sub-regions of the second conductive region, respectively.

21. A semiconductor device structure comprising:
a semiconductor bulk substrate with an original surface;
an active region within the semiconductor bulk substrate, wherein the active region comprises a plurality of transistors, each transistor comprises a gate structure with a bottom surface under the original surface, a first conductive region electrically coupled to the bulk substrate, and a second conductive region;
a STI region surrounding the active region; and
an interconnection layer extended beyond at least one transistor of the plurality of transistors and electrically coupled to the at least one transistor at a connection position under the gate structure of the at least one transistor.

22. The semiconductor device structure of claim 21, wherein the interconnection layer is a bit line extended beyond the plurality of transistors and electrically coupled to each of the plurality of transistors at a connection position under the gate structure of each transistor, respectively.

23. The semiconductor device structure of claim 21, wherein the interconnection layer is disposed within the STI region and under the original surface and is isolated from the semiconductor bulk substrate, and the first conductive region of the at least one transistor is directly or indirectly connected to a sidewall of the interconnection layer.

24. The semiconductor device structure of claim 21, the at least one transistor further comprising two vertical channel regions separate from each other, wherein the first conductive region of the at least one transistor is electrically connected to the two sub-regions of the second conductive region of the at least one transistor through the two vertical channel region.

25. The semiconductor device structure of claim 24, further comprising a highly doped semiconductor region next to one of the two vertical channel regions, the highly doped semiconductor region extends downward from the original surface and a dopant type of the highly doped semiconductor region is different from that of the first conductive region.
